(19) United States
(12) Patent Application Publication
(10) Pub. No.: US 2011/0011641 A1
(43) Pub. Date: Jan. 20, 2011

(54) JUNCTION BOX FOR SOLAR MODULES

(75) Inventor: Roland Pfeffer, Leutkirch (DE)

Correspondence Address: BOHAN MATHERS, PO BOX 17707, PORTLAND, ME, 04112-8707, US

(73) Assignee: FPE Fischer GmbH, Leutkirch (DE)

(21) Appl. No.: 12/921,899

(22) PCT Filed: Mar. 11, 2009
(86) PCT No.: PCT/DE09/00330

§ 371 Date: Sep. 10, 2010

(30) Foreign Application Priority Data
Mar. 13, 2008 (DE) 10 2008 013 930.0
May 6, 2008 (DE) 10 2008 022 298.4

(51) Int. Cl. H05K 7/20

(52) U.S. Cl. 174/547

(57) ABSTRACT

The invention relates to a junction box which safely dissipates heat produced by electrical/electronic components assembled in the box. The junction box has a housing with cover and at least one component chamber that juts out from a side wall of the housing. The component chamber has cooling fins. An electric or electronic component, sheathed in insulation, is inserted into the component chamber, such that it fits firmly against the walls of the chamber. The cover has cooling fins and overhangs the body of the housing and the component chamber in several areas. The construction of the junction box with the component chambers that jut out from the body and the housing cover with overhang enhance heat dissipation and allow the box to be used with solar modules in which bypass flows up to 16 A and greater occur.

### BACKGROUND INFORMATION

1. Field of the Invention

The invention relates to a junction box which reliably dissipates the heat produced in the bypass diodes, MOSFETs or corresponding power semiconductors of a solar module.

2. Description of the Prior Art

During the operation of a solar installation, it is never possible to wholly exclude the shading of individual solar cells, for example due to clouds or falling leaves. Without protective measures, the so-called Zener effect would produce high power loss in the shaded solar cell, leading to a hot spot in this cell and, thus, almost always to destruction of the particular cell.

For this reason, electronic components such as bypass diodes, MOSFETs, or comparable power semiconductors are typically connected in parallel to the solar cells or rows of series-connected solar cells. When shaded, the particular shaded cell or row of cells is thus bridged by the electronic component, thereby ensuring that the current produced by the unshaded cells continues to flow, without, however, risking destruction of the solar cells.

When a solar cell is shaded, the electronic components must handle high power levels. If they are not adequately cooled, such components become very hot, which permanently shortens their service life. In extreme cases, overheating may lead to immediate failure of the components.

The electronic components are usually assembled in junction boxes which serve to interconnect the individual solar modules. Junction boxes made of plastic (DE 203 11 184 U1, DE 11 2005 002 898 T5 and EP 1 102 354 A2, among others) are often used for this purpose, although such boxes are very poor at conducting conduct the heat away.

DE 10 2004 010 658 A1 suggests lining the junction box with silicone resin, which has a relatively good thermal conductivity, and to construct the cover of the box as a metal plate coated with a weather-resistant resin. The heat dissipation, however, remains inadequate. Furthermore, it is practically impossible to replace defective components.

The number of solar systems being installed is increasing and the demand for junction boxes increases accordingly. At the same time, greater demands are being placed on the quality of the boxes. In addition, cost pressures are mounting as a result of the tariff degression stipulated in the Renewable Energy Sources Act (EEG). The trend is also towards ever more powerful solar modules, in which reverse currents of 8 . . . 16 A occur. The conventional boxes in the market, however, are to date mostly designed to handle currents only up to a maximum of 8 A.

The prior art, as a result, has recently disclosed junction boxes which guarantee improved heat dissipation of the electronic components (for example DE 100 50 614 C1, WO 2006/117895 A1, U.S. Pat. No. 7,288,717 B1 and DE 10 2004 036 697 A1).

DE 10 2006 027 104 B3 describes a junction box in which the electronic components are pressed into recesses corresponding to the geometry of the components by means of pressure elements, for example spring clips, whereby electrical insulation, preferably a thermally conductive silicone rubber, is provided between the housing and the components.

DE 10 2005 022 226 A1 discloses an arrangement for heat dissipation for electronic components that are assembled in a housing (for example, a connector box for photovoltaic modules), in which a cover plate provided with a heat sink is pressed onto the components that are subject to thermal loading. The heat sink is an extruded aluminum profile and the housing base is made of injection-molded plastic. Only the heat sink on the cover is used here for heat dissipation, but, because extruded profiles display a significantly higher thermal conductivity, which also means cooling effect, than cast aluminum, the greater cooling effect compensates to a large extent this disadvantage. The improved cooling effect of heat sinks or housings comprising extruded aluminum profiles is used, for example, in DE 102 49 436 A1 and U.S. Pat. No. 6,374,912 B1.

Both solutions achieve improved heat dissipation and also ensure electrical insulation between the components and the housing. it is assumed, however, that the housing takes the form of a box in which the components are located in recesses in the side walls or pressed against the housing cover. This compact arrangement results in inferior heat dissipation from the components, compared to a design in which the housing deviates from a box form, so as to achieve a greater ratio of surface area to volume.

### BRIEF SUMMARY OF THE INVENTION

The objective of the present invention is to produce a junction box which guarantees improved heat dissipation away from electrical components' assembled in the junction box.

The junction box for solar modules according to the invention comprises a housing constructed with at least one receiving or component chamber that projects outward from the body of the housing, so as to facilitate heat dissipation away from an electrical/electronic component that is retained in the chamber. The housing includes a housing body and a housing cover mounted on the body. Electrical components and electrical connections are assembled within the junction box housing. According to the invention, at least one component chamber is provided in at least one side wall, in such a way, that the component chamber projects distally outward from the side wall, as a balcony projects outward from a building wall. An electrical component that is sheathed in an insulating covering is inserted into the component chamber, such that the component is in firm contact with the inner walls of the component chamber and with the cover.

In this embodiment, at least one electrical component assembled in the junction box is an electronic component, such as a diode, a MOSFET, or another power semiconductor, which serves to protect the solar modules. Bypass diodes or bypass MOSFETs are typically used for this purpose.

Re-locating the electrical components outward from the main body of the housing results in sustained improvement of the cooling of the components. Furthermore, with this structural arrangement of component chambers, the housing body, which is usually mounted on the rear side of the solar modules, heats up less during operation, and this, in turn, reduces the likelihood of excessive heating of the solar modules.

The insulation coverings are preferably silicone rubber sheathings. The thickness of the sheathing usually varies within the range of millimeters, thereby providing high-voltage-strength insulation. The use of silicone rubber also ensures even pressure distribution of the component in the chamber and also a good thermal interface. Assembly aids, such as clips and braces, may be dispensed with.

The housing cover is of extruded aluminum and has several cooling fins. It has been shown that extruded aluminum parts possess a thermal conductivity approximately three times greater than that of adequate die-cast aluminum parts.

Advantageously, the housing cover is of such size that it overhangs the contour of the housing body. Cooler air flows over both sides of the cover in the area of overhang and this increases the cooling effect of the cover. Furthermore, the fluid dynamics of the cooling air are enhanced by the formation of a chimney effect. The oversize housing cover also provides improved protection against mechanical influences for the cable passages and cemented joints.

Three or four electrical components, such as, for example, bypass diodes or bypass MOSFETS, are typically assembled inside a junction box. The trend, however, is moving in the direction of higher-performance solar modules, so that, in future, the number of electrical components which must be accommodated in each box may increase, which is readily possible with the junction box according to the invention.

### BRIEF DESCRIPTION OF THE DRAWINGS

The junction box according to the invention is explained below in greater detail by way of an embodiment. The following figures are provided.

FIG. 1 is a top plan view of the open junction box according to the invention.

FIG. 2 is a perspective view of the junction box of FIG. 1, with a plastic cover.

FIG. 3 is a perspective view of the closed junction box of FIG. 1.

### DETAILED DESCRIPTION OF THE INVENTION

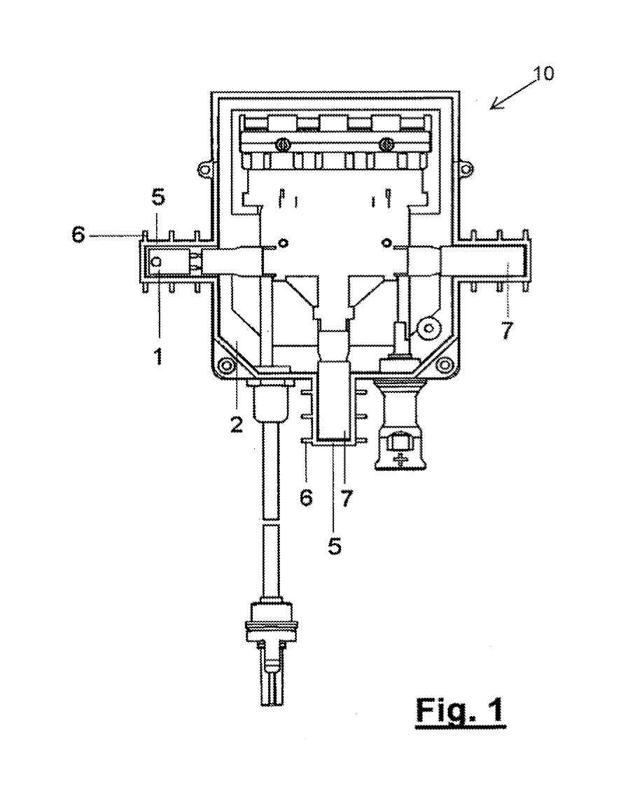

FIGS. 1-3 illustrate a junction box 10 according to the invention. The junction box comprises a die-cast aluminum housing body 2, a housing cover 3, and at least one component chamber 5 for retaining a component. In the embodiment shown, three component chambers 4 are provided on the side walls of the housing body 2. This illustration is by way of example only and is not intended to be limiting. As shown, the component chamber 5 projects distally outward from the sidewall in the manner of a balcony. An electrical component 1, for example, a bypass diode, that is to be assembled in a component chamber 5 is sheathed in an insulation covering 7 and inserted into the chamber 5 so as to be in firm contact with the inner walls of the chamber 5 and with the housing cover 3. A suitable insulation material for the covering 7 is thermally conductive silicone rubber, because of its heat dissipation and cushioning properties. The component chamber 5 has cooling fins 6, to facilitate heat dissipation.

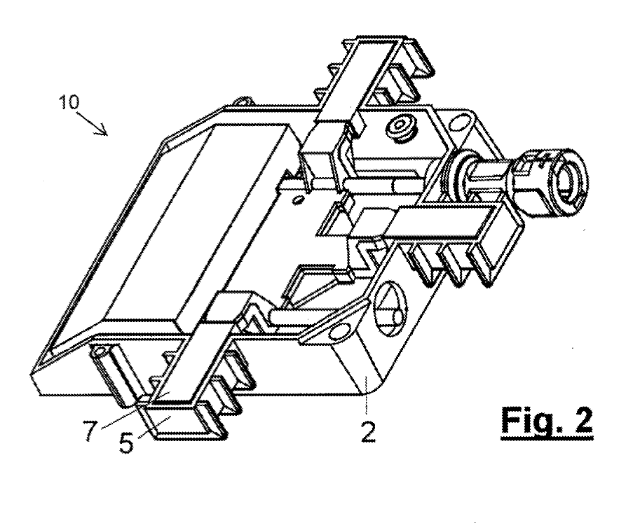

FIG. 2 illustrates the bottom of the junction box 10. The bottom plane of the component chamber 5 with the insulated component is elevated, relative to the overall plane of the bottom of the housing body 2. This is due to the geometry of the component 1, but also has the advantage of improving the cooling effect on the component 1.

The insulating covering 7 is approximately 1 mm thick, which provides sufficient protection for the component 1, i.e., a bypass diode, against overvoltage damage. The insulating covering 7 also serves as a heat transfer layer.

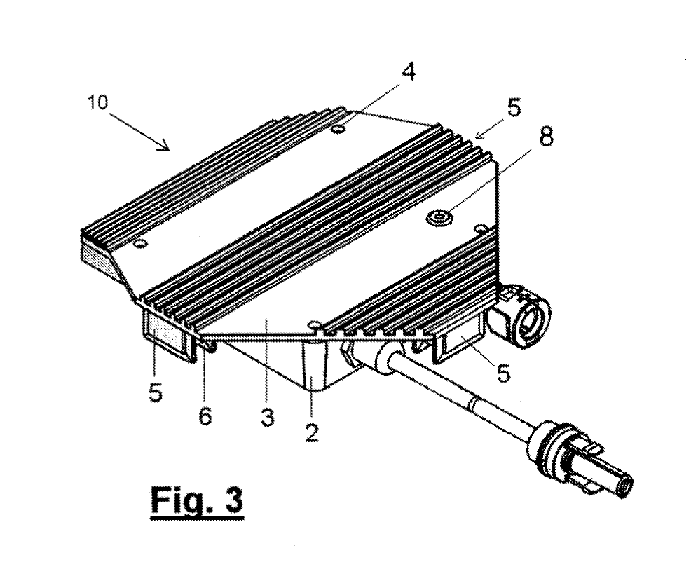

As illustrated in FIG. 3, the extruded aluminum housing cover 3, which has cooling fins and is assembled on the housing body 2 with four screws 4, completely covers the three component chambers 5 and overhangs significantly beyond the contour of the housing body 2 in several areas. The overhang areas on the housing cover 3 serve as double-sided heat sinks. Furthermore, the chimney effect that occurs provides better air flow over and around the housing cover 3. The improved cooling enables use of the junction box 10 in installations in which bypass currents of up to 16 A and greater occur. It is also possible, if necessary, to accommodate four or more bypass diodes or components 1 by providing the desired number of component chambers 5.

To guarantee adequate pressure compensation in the junction box, a watertight but air-permeable membrane of non-woven composite material 8 is provided in the housing cover 3.

1. A junction box for solar modules, the junction box comprising:
a housing having a housing body with sidewalls and a housing cover;
at least one component chamber provided in at least one sidewall of the sidewalls;
wherein the component chamber juts out away from the at least one sidewall, so as to have three component-chamber sidewalls;
wherein the housing cover, when assembled on the housing body, covers the housing body, including the at least one component chamber, and further has an overhang beyond the housing body and the component chamber, so as to provide an enhanced heat-dissipation area.

2-11. (canceled)
